(19) United States
(12) Patent Application Publication
(10) Pub. No.: US 2007/0164791 A1
(43) Pub. Date: Jul. 19, 2007

(54) Low voltage detect and/or regulation circuit

(76) Inventors: T. V. Chanakya Rao, Bangalore (IN); Badrinarayanan Kothandaraman, Bangalore (IN)

Correspondence Address: WALKER & SAKO, LLP, Suite 235, 300 South First Street, San Jose, CA, 95113, US

(21) Appl. No.: 11/653,540

(22) Filed: Jan. 16, 2007

Related U.S. Application Data
(60) Provisional application No. 60/779,152, filed on Mar. 2, 2006.

(30) Foreign Application Priority Data
Jan. 17, 2006 (IN) 66/CHE/2006

(51) Int. Cl. H03K 5/22

(52) U.S. Cl. 327/77

(57) ABSTRACT

A low voltage detect and supply circuit (200) can include a detect circuit (202), a bias circuit (204) and a power supply transistor structure (P1). In operation, when a device power supply (Vext) remains above a predetermined limit, a detect circuit (202) can provide low impedance, thus maintaining transistor structure P1 in a high impedance state. When a device power supply (Vext) falls below a predetermined limit, a detect circuit can provide a high impedance. Embodiments of the circuit (200) do not include a differential voltage type comparator, and can be biased to draw relatively small amounts of current.

This application claims the benefit of U.S. Provisional Patent Application Ser. No. 60/779,152, filed on Mar. 2, 2006, the contents of which are incorporated by reference herein.

### TECHNICAL FIELD

The present invention relates generally to integrated circuit devices that include an internal regulated power supply level generated from an externally received power supply level, and more particularly to low voltage detect and supply circuits that detect when the externally received power supply level falls below a predetermined level and/or a regulated power supply falls below a minimum level.

### BACKGROUND OF THE INVENTION

In many integrated circuit designs it can be desirable to provide an internally generated power supply voltage from an externally received power supply voltage. An internal power supply voltage is typically a “regulated” voltage that is controlled to maintain some minimum (or maximum) internal supply voltage. As but one particular example, an integrated circuit may include memory cells, or the like, in which a data retention capability can require some minimum potential. Thus, a voltage regulation capability can be implemented to maintain some minimum data retention voltage.

A voltage regulation circuit can often include a low voltage detect circuit. A low voltage detect circuit can detect when an externally received power supply voltage drops a predetermined amount. Additionally, some sort of regulation circuit can be included that is activated in the event of a low supply voltage event in order to ensure the minimum internal supply voltage is maintained.

To better understand various features of the disclosed embodiments, a conventional low voltage detect circuit will now be described. A conventional low voltage detect circuit is set forth in FIG. 9 and designated by the general reference character 900. A conventional low voltage detect circuit 900 can include a reference leg 902, a detect leg 904, and a differential comparator 906. A reference leg 902 can include transistors M91, M92 and N91 having source-drain paths arranged in series between an external power supply voltage Vext and a low voltage Vgnd. Transistors M91 and M92 can be “native” n-channel metal-oxide-semiconductor (MOS) type transistors. A “native” transistor can be one that is not subject to any threshold voltage implant/diffusion steps to raise its threshold voltage. Thus, such a transistor can have a threshold voltage at about zero volts (e.g., from about −150 mV to about +150 mV depending upon process and temperature variation). Transistor N91 can be a low voltage n-channel MOS transistor. In the conventional circuit shown, a low voltage transistor is a transistor that is not designed to withstand a potential greater than about 5.0 volts.

A reference leg 902 can generate a signal “B” that can have a value given by the relationship:

B=V_{tn LVNMOS}−2*V_{tn Native}

where V_{tn LVNMOS} is a threshold voltage of transistor N91 and V_{tn Native} is a threshold voltage of transistors M91 and M92.

A detect leg 904 can include transistor N92 and N93 coupled in series between external power supply voltage Vext and low power supply voltage Vgnd. Transistors N92 and N93 can be low voltage n-channel MOS transistors like transistor N91.

A detect leg 902 can generate a signal “A” that can have a value given by the relationship:

A=Vₑₓₜ−V_{tn LVNMOS}

where Vₑₓₜ is the external voltage level.

Comparator 906 can have inputs (+) and (−), and can amplify a differential potential between such terminals to drive an output (LVDET) high or low. In the arrangement of FIG. 9, comparator 906 can receive signal A at a (+) input and signal B at a (−) input, and provide a low voltage detect signal LVDET in the event of a low voltage condition. Even more particularly, signal LVDET can transition from low to high when at a given trip point given by the following relationship, and simplified relationship:

Vₑₓₜ−V_{tn LVNMOS}<=V_{tn LVNMOS}−2*V_{tn Native}

Vₑₓₜ<=2*(V_{tn LVNMOS}−V_{tn Native})

Vₑₓₜ<=˜1.8V.

A drawback to a conventional low voltage detect circuit like that shown in FIG. 9 can be the amount of current drawn by the circuit. In particular, circuit 900 includes a comparator 906, and comparators can typically draw a current that can be undesirably large, particularly in low power applications. Even more particularly, a conventional circuit 900 in some implementation can draw about 120 nA.

It would be desirable to arrive at a low voltage detect circuit that does not draw as much current as a conventional circuit like that of FIG. 9.

In addition, it is always desirable to arrive at more compact implementations for a circuit or circuit function in a large integrated circuit device.

### BRIEF DESCRIPTION OF THE DRAWINGS

FIG. 1 is a block schematic diagram of a voltage regulation arrangement according to embodiments of the present invention.

FIG. 2 is a block schematic diagram of a low voltage detect and supply circuit according to one embodiment of the present invention.

FIG. 3 is a block schematic diagram of a voltage sustain circuit according to one embodiment of the present invention.

FIG. 4 is a block schematic diagram of memory device according to an embodiment of the present invention.

FIG. 5 is a schematic diagram of a low voltage detect and supply circuit according to one embodiment of the present invention.

FIG. 6 is a schematic diagram of a voltage sustain circuit according to one embodiment of the present invention.

FIG. 7 is a schematic diagram of a bias circuit that can be used with the embodiments shown in FIGS. 5 and 6.

FIG. 8 is a top plan view showing the formation of a “native” transistor that can be included in the above embodiments.

FIG. 9 is a schematic diagram of a conventional low voltage detect circuit.

### DETAILED DESCRIPTION

Various embodiments of the present invention will now be described in detail with reference to a number of drawings. The embodiments show circuits and methods for a detecting a low voltage condition at a device power supply voltage. In addition, the embodiments show a circuit for coupling a regulated power supply node to a device power supply node in the event of such a low voltage condition. Still further, the embodiments also include circuits for maintaining some minimal potential in the event an internal power supply falls below a minimum level (internal power supply “collapses”).

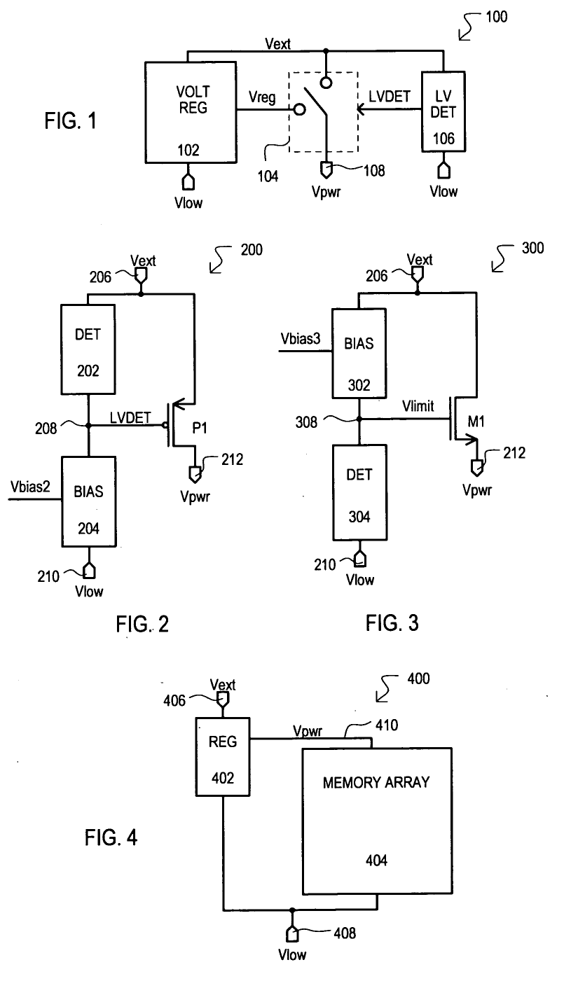

A low voltage detect and regulation arrangement, like those examples in the below embodiments, is shown in a conceptual view in FIG. 1, and designated by the general reference character 100. An arrangement 100 can include a voltage regulator 102, a supply switch 104, and a low voltage detector 106. A voltage regulator 102 can generate a regulated voltage Vpwr based on a higher device power supply voltage Vext.

A supply switch 104 can provide either a regulated voltage Vreg or a device power supply voltage Vext to an internal power supply node 108 in response to a low voltage detect signal LVDET. If signal LVDET is inactive (no low voltage condition detected), a switch can provide regulated voltage Vreg as an internal power supply voltage Vpwr. If signal LVDET is active (low voltage condition detected), a switch can provide device power supply voltage Vext as an internal power supply voltage Vpwr.

A low voltage detector 106 can determine when a device power supply voltage Vext falls below a predetermined level. When such an event occurs, a low voltage condition can exist and a signal LVDET can be activated.

A block schematic diagram of a circuit according to one embodiment is set forth in FIG. 2, and designated by the general reference character 200. A low voltage detect and supply circuit 200 can include a detect circuit 202, a bias circuit 204 and a power supply transistor structure P1. A detect circuit 202 can be situated between a device power supply voltage node 206 and a control node 208. In operation, when a device power supply Vext at node 206 remains above a predetermined limit, a detect circuit 202 can provide low impedance, thus maintaining transistor structure P1 in a high impedance state. When a device power supply Vext at node 206 falls below a predetermined limit, a detect circuit 206 can provide a high impedance.

A bias circuit 204 can be situated between control node 208 and a reference supply voltage node 210. A bias circuit 204 can receive a bias voltage Vbias2, and enable a bias current to flow from control node 208 to a reference supply voltage node 210. Thus, when detect circuit 202 has a high impedance, bias circuit 204 can pull control node 208 low, placing transistor structure P1 into an enabled state.

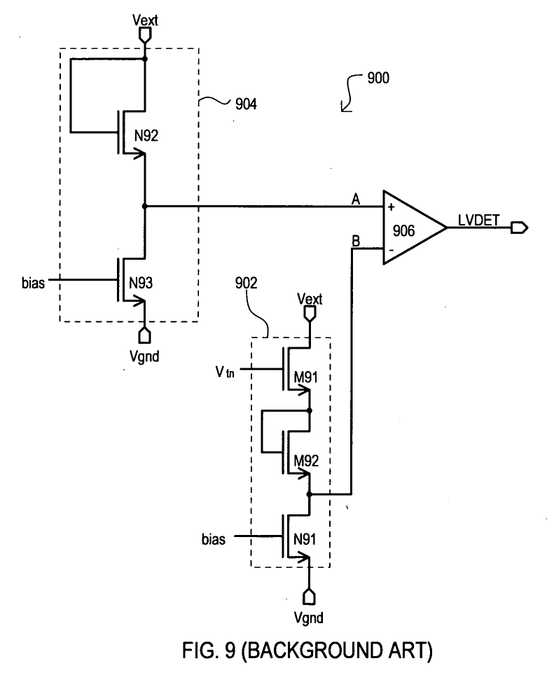

A bias circuit 204 can be designed to draw a considerably smaller current than a differential comparator circuit, like that shown in FIG. 9. Preferably, a bias circuit can draw less than 50 nA, preferably less than 20 nA, even more preferably less than 12 nA.

A transistor structure P1 can include one or more transistors having source-drain paths arranged in parallel with one another between a device power supply node 206 and an internal power supply node 212, and a gate coupled to control node 208. Preferably, transistor structure P1 includes one or more p-channel insulated gate field effect transistors (IGFETs). P-channel transistors of transistor structure P1 can have a typical complementary metal-oxide-semiconductor (CMOS) threshold voltage. In one embodiment, threshold voltages can be no more than about −0.5 volts, even more preferably no more than about −0.25 volts, even more preferably, no more than about −200 mV.

In this way, when a device power supply voltage Vext is above some predetermined limit, transistor structure P1 can provide a high impedance path, enabling some lower regulated voltage to be provided to internal power supply node 212. When a device power supply voltage Vext falls below the predetermined limit, transistor structure P1 can provide a low impedance path, connecting internal power supply node 212 essentially directly to device power supply node 206.

While one embodiment of the present invention can include a low voltage and detect circuit 200, embodiments may also include a circuit for maintaining an internal power supply voltage at some minimum level even if a power supply voltage is at an acceptable level. A circuit for doing so according to one embodiment is set forth in FIG. 3.

FIG. 3 shows a voltage sustain circuit according to one embodiment that is designated by the general reference character 300. A voltage sustain circuit 300 can include some of the same general power supply nodes as FIG. 2, thus like nodes are referred to by the same reference characters. The voltage sustain circuit 300 of FIG. 3 can include a sustain bias circuit 302, a sustain detect circuit 304, and a sustain transistor structure M1. A sustain bias circuit 302 can be situated between a sustain bias node 308 and a device supply voltage node 206 and receive a bias voltage Vbias3. In response, sustain bias circuit 302 can enable a bias current to flow from device power supply node 206 to sustain bias node 308.

A sustain bias circuit 302 can be designed to draw a considerably small current with respect to a differential comparator circuit, like that shown in FIG. 9. Preferably, a sustain bias circuit can draw less than 15 nA, preferably less than 10 nA, even more preferably less than 7 nA.

A sustain detect circuit 304 can be situated between sustain bias node 308 and a reference supply node 210. In operation, when an internal power supply voltage Vpwr at node 212 is above a predetermined sustain limit, a sustain detect circuit 304 can provide low impedance, thus maintaining transistor structure M1 in a high impedance state. When an internal power supply voltage Vpwr falls below a predetermined limit, a sustain detect circuit 304 can provide a high impedance. Due to sustain bias circuit 302, such a high impedance can result in sustain bias node 308 being pulled high, which can place transistor structure M1 in a low impedance state, thereby connecting internal power supply voltage node 212 to device power supply node 206.

A sustain transistor structure M1 can include one or more transistors having source-drain paths arranged in parallel with one another between a device power supply node 206 and an internal power supply node 212, and a gate coupled to sustain bias node 308.

Preferably, transistor structure M1 includes one or more n-channel IGFETs. Such n-channel transistors can be low threshold voltage n-channel IGFETs. As but one example, such transistors can have threshold voltages less than those of other n-channel transistors within the circuit. In another example, such transistors can have a threshold voltage that varies from a low power supply level (Vlow) by no more than about 200 mV. Even more particularly, a low power supply voltage (Vlow) can be ground (0 volts), and such transistors can have threshold voltages in the general range of about +100 mV to about −100 mV. Still further, such low threshold voltage transistors can be “native” devices: transistors that are not subject to any threshold voltage implant/diffusion steps to raise its threshold voltage.

The above embodiments have described a low voltage detect circuit and sustain circuit that can be used alone or in combination. One particularly advantageous application for such circuits is shown in one embodiment in FIG. 4.

FIG. 4 shows a memory device 400 having a regulation section 402 and a memory array section 404. A regulation section 402 can include any low voltage detect and/or sustain circuit described above or below. As such, a regulation section 402 can be connected between a high power supply voltage node 406 and a low power supply node 408. In addition, regulation section 402 can control the potential at an internal power supply node 410 according to the various structure and techniques set forth in the described embodiments.

A memory array section 404 can include one or more memory cell arrays with corresponding circuits (e.g., decoders, sense amplifiers, input/output circuits, etc.). Because such structures can be conventional, a detailed description has been omitted. A memory array section 404 can receive power via internal power supply node 410 and low power supply node 408.

Memory cells within memory array section 404 can include any of various conventional memory cells including, without limitation, dynamic random access memory (DRAM) cells (including pseudo static RAM cells), electrically erasable and programmable read only memory (EEPROM), ferroelectric RAM (FRAM) cells, and/or magneto resistive RAM (MRAM) cells. Preferably a memory array section 404 can include static RAM memory cells having a minimum data retention voltage. A minimum data retention voltage can be a minimum voltage below which data retention within a memory cell cannot be guaranteed. In one very particular example, SRAM memory cells can include cross-coupled n-channel transistors (e.g., transistors with commonly connected sources and gates connected to the drain of the other transistor of the pair), and a minimum data retention value can be a threshold voltage of a standard n-channel IGFET (e.g., not a low threshold voltage transistor).

Various more detailed embodiments will now be described.

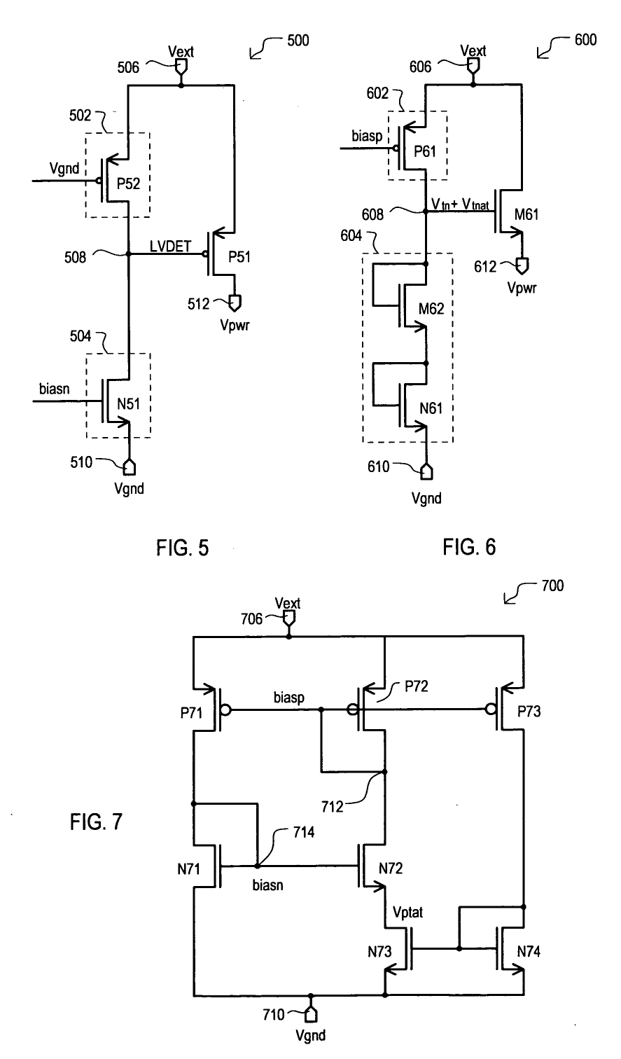

FIG. 5 shows a more detailed low voltage detect and supply circuit 500 according to another embodiment. A low voltage detect and supply circuit 500 can include many of the circuit sections as those shown in FIG. 2. Accordingly, like sections are referred to by the same reference character but with the first digit being a “5” instead of a “2”.

In the low voltage detect and supply bias circuit 500 of FIG. 5, a detect circuit 502 can include a p-channel IGFET P52 having a source-drain path coupled between a high power supply node 506 and a control node 508, and a gate coupled to a low voltage supply (Vgnd). P-channel transistor P52 can have a typical CMOS threshold voltage, as described above. In one particular arrangement, a p-channel transistor can have width/length (W/L) dimensions of about 0.63/200 microns.

It is understood that when transistor P52 is in saturation, it can present a source-drain voltage drop that will be referred to herein as an “overdrive” voltage.

A control node 508 can provide a low voltage detect signal LVDET.

A transistor structure P51 of the circuit 500 shown in FIG. 5 can preferably include multiple p-channel IGFETs with source-drain paths arranged in parallel with one another. Such transistors can have typical p-channel CMOS threshold voltages as noted above. In one particular arrangement, a transistor structure can include 60 transistors arranged in parallel, each having width/length (W/L) dimensions of about 4.0/1.5 microns.

Referring still to FIG. 5, a bias circuit 504 can include an n-channel IGFET N51 having a source-drain path coupled between a control node 508 and a low power supply node 510, and a gate coupled to a bias voltage (biasn). One example of a circuit for generating bias voltage (biasn) will be described in more detail below. In one particular arrangement, transistor N51 can be biased to draw 10 nA (provided sufficient current is being sourced via transistor P52).

Preferably, n-channel transistor N51 can be a low voltage transistor. A low voltage transistor can one of a majority of transistors in an integrated circuit designed to withstand a predetermined voltage level across its terminal. In one embodiment, a low voltage transistor is a transistor that is not designed to withstand a highest received power supply voltage (Vext). In another embodiment, a low voltage transistor is a transistor that is not designed to withstand a potential greater than 6.0 volts, preferably no greater than 5.0 volts, even more preferably no greater than 3.5 volts.

Still further, n-channel transistors N51 can have a typical CMOS threshold voltage. In one embodiment, such a threshold voltage can be no less than about 0.5 volts, even more preferably no less than 0.25 volts, even more preferably, no less than 200 mV.

The circuit of FIG. 5 can operate in the following fashion.

If Vext<Vtp+V_{P52}_{_{—}}_{OVERDRIVE}, signal LVDET at control node 508 can be pulled low (e.g., to zero volts) by operation of bias circuit 504, where Vtp is a threshold voltage of transistor P51 (and P52), and V_{P52}_{_{—}}_{OVERDRIVE} is the “overdrive” voltage of transistor P52 as described above. When signal LVDET is driven low, transistor structure P51 can provide a low impedance. As a result an external power supply voltage Vext can be essentially shorted to internal power supply node 512.

In this way, a low voltage condition at power supply node 506 can be detected, and then addressed by directly connecting an external power supply voltage (Vext) as an internal power supply voltage (Vpwr).

If Vext>Vtp+V_{P52}_{_{—}}_{OVERDRIVE}, signal LVDET pulled high (e.g., to about Vext) by operation of transistor P52 “overpowering” transistor N51. With signal LVDET driven high, transistor structure P51 can provide a high impedance. As a result an external power supply voltage Vext can be isolated from an internal power supply node 512, allowing internal voltage Vpwr to be regulated according to some other circuit.

In this way, provided a device power supply Vext is high enough, low voltage detect and supply circuit 500 can isolate a high power supply Vext from an internal power supply Vpwr. It is noted that in such a state, a current drawn by transistor N51 remains considerably small as compared to conventional approaches.

FIG. 6 shows a more detailed voltage sustain circuit 600. A voltage sustain circuit 600 can include many of the circuit sections as those shown in FIG. 3. Accordingly, like sections are referred to by the same reference character but with the first digit being a “6” instead of a “3”.

In the voltage sustain circuit 600 of FIG. 6, a sustain bias circuit 602 can include a p-channel IGFET P61 having a source-drain path coupled between a high power supply node 606 and a sustain bias node 608, and a gate coupled to a bias potential (biasp). P-channel transistor P61 can have a typical CMOS threshold voltage, as described above. In one particular arrangement, transistor P61 can be biased to draw about 5 nA.

A sustain detect circuit 604 can include an n-channel IGFET M62 connected in a diode configuration (gate connected to drain) in series with n-channel IGFET N61, also connected in a diode configuration. Transistor M62 can be a low threshold voltage transistor as described with reference to transistor M1 of FIG. 3. Transistor N61 can be a low voltage transistor with typical CMOS threshold voltage as noted above with reference to transistor N51 of FIG. 5. In one particular arrangement, transistor M62 can have W/L dimensions of about 0.5/20 microns, and transistor N61 can have W/L dimensions of about 0.5/20 microns.

A transistor structure M61 of the circuit 600 shown in FIG. 6 can preferably include multiple n-channel IGFETs with source-drain paths arranged in parallel with one another. Such transistors can be low voltage threshold transistors as described with reference to transistor M1 of FIG. 3. In one particular arrangement, a transistor structure can include 20 transistors arranged in parallel, each having W/L dimensions of about 4.0/1.0 microns.

In operation, voltage sustain circuit 600 can function like a clamping circuit to maintain internal power supply node at a level of an n-channel threshold voltage (Vtn) in the event the potential (Vpwr) at internal power supply node 612 falls below such a level. More particularly, sustain detect circuit 604 can maintain sustain bias node 608 at a potential of Vtn+Vtnat, where Vtnat is the threshold voltage of a low threshold voltage transistor, such as M61 and M62. Thus, when a potential at internal power supply node 612 is less than Vtn, transistor M61 will turn on, coupling device power supply node 606 to internal power supply node 612.

As but one example, when utilized in a memory device like that shown in FIG. 4, a voltage sustain circuit can be utilized in a data retention mode to ensure some minimal voltage can be maintained.

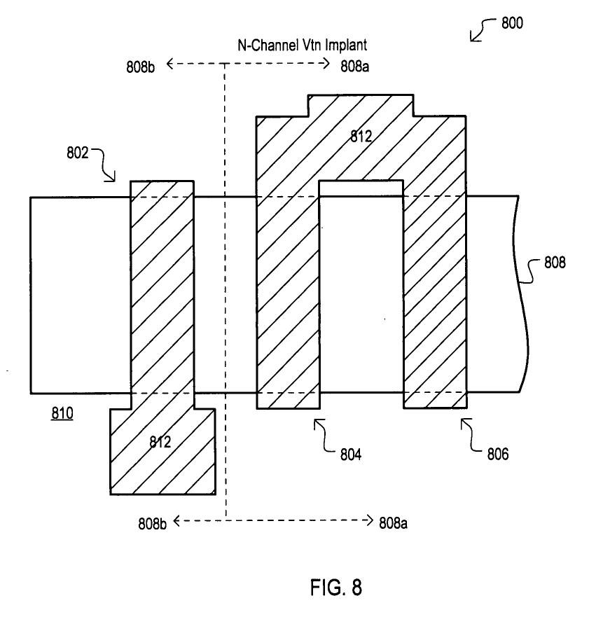

It is noted that the embodiments of FIGS. 5 and 6 show arrangements in which a bias voltage (e.g., biasn and/or biasp) can be applied to provide a low bias current. In some cases it may be desirable to generate such bias voltages without the use of resistors, which can consume power and occupy large amounts of substrate area. One particular example of such a resistor-less bias circuit is shown in FIG. 7.

FIG. 7 shows a resistor-less bias circuit 700 that can be used in conjunction with embodiments like that of FIGS. 5 and 6. A bias circuit 700 can be connected between a device power supply node 706 and a low power supply node 710. A bias circuit 700 can include a first current mirror formed by p-channel IGFETs P71-P73 and a second current mirror formed by n-channel IGFETs N71 and N72. A bias level for the circuit can be established by bias circuit formed with transistors N73 and N74.

Transistors P71 to P73 can have sources connected to device power supply node 706 and commonly connected gates. In addition, a gate of transistor P72 can be connected to its drain. Common gates of transistors P71 to P73 can be formed at a first reference bias node 712 that can carry a reference bias potential “biasp”. Such a bias voltage can be provided to circuit 600 of FIG. 6 (at gate of transistor P61). P-channel transistors P71-P73 can have typical CMOS threshold voltages, as noted above with respect to transistor P61.

An n-channel transistor N71 can have a drain and gate connected to a drain of transistor P71 and a source connected to a low power supply node 710. Transistor N72 can have a drain connected to a drain of transistor P72 and a gate connected to a gate of transistor N71. Common gates of transistors N71 and N72 can be formed at a second reference bias node 714 that can carry a reference bias potential “biasn”. Such a bias voltage can be provided to circuit 500 of FIG. 5 (at gate of transistor N51).

N-channel transistors N71 and N72 can have typical CMOS threshold voltages, as noted above with respect to transistor N51. In one arrangement, transistor N72 can have W/L dimensions that are scaled with respect to those of transistors P71-P73. Even more particularly, transistors can have W/L sizes of Wp/L where Wp is a CMOS p-channel transistor width (which can be twice that of an n-channel transistor width). Transistor N72 can have a size of S*Wn/L, where Wn is a CMOS n-channel transistor width, and S is a multiplying factor.

In the bias circuit 700 of FIG. 7, transistors N71 and N72 can operate in a sub-threshold region and generate a potential Vptat, which can be a voltage that is proportional to absolute temperature. Such a voltage can be converted into a current by operation of transistor N73, which operates in the linear region (i.e., essentially as a resistor). In such an arrangement, a current drawn by the circuit can be given by:

I=8*βₙ₄*V_{T}²*In²(S),

where βₙ₄ is the beta of transistor N73, V_{T} is the thermal voltage (V_{T}=K*T/q), and S is the scaling factor noted above.

As noted above, in particular embodiments, a voltage sustain circuit (e.g., 200 and/or 600) can include “native” n-channel transistors. FIG. 8 shows one very particular example of how such devices can be formed.

FIG. 8 is top plan view of n-channel transistors at a gate level. A layout 800 can include a “native” device 802 and two “standard” devices 804 and 806 formed in an active area 808 surrounded by isolation 810.

One portion 808a of active area 808 can be subject to a threshold implant step that can raise a threshold voltage of transistors 804 and 806 (prior to the formation of gates 812 and/or sources/drains). Another portion 808b of active area 808 can be isolated from such a manufacturing step.

Embodiments like those of FIGS. 5 and 6 can provide voltage regulation with relatively high accuracy. For example, such circuits can provide a maximum of about ±150 mV over expected variations in manufacturing process, temperature and/or operating voltage. Even more particularly, embodiments like those of FIGS. 5 and 6 can provide an internal power supply voltage of about 1.25 V±150 mV. However, such regulation can depend upon threshold voltages of p-channel devices. In processes and/or manufacturing lots with a higher degree of p-channel threshold voltage control, such variations may be as little as ±50 mV.

Still further, in embodiments like those of FIGS. 5 and 6, by avoiding the use of a differential type comparator circuit, very low power operation can be achieved. In particular, current drawn can be about 15 nA. This is in sharp contrast to 120 nA of a conventional approach like that of FIG. 9.

The embodiments shown in FIGS. 5 and 6 can provide advantageously compact circuits. In particular, detection sections (e.g., 502 and 604) and biasing sections (e.g., 504 and 602) can be formed of single transistors.

It is understood that the embodiments of the invention may be practiced in the absence of an element and or step not specifically disclosed. That is, an inventive feature of the invention can be elimination of an element.

Accordingly, while the various aspects of the particular embodiments set forth herein have been described in detail, the present invention could be subject to various changes, substitutions, and alterations without departing from the spirit and scope of the invention.

What is claimed is:

1. A low voltage detect and supply circuit, comprising:
at least one power supply transistor having a source connected to a power supply node, a gate coupled to a control node, and a drain coupled to a regulated supply node;
a detect circuit having a controllable impedance path coupled between the power supply node and the control node that provides an impedance that varies according to a potential between the power supply node and the control node; and
a bias circuit coupled between the control node a reference supply node that enables a bias current for the detect circuit.

2. The low voltage detect and supply circuit of claim 1, wherein:
the detect circuit and bias circuit consist of no more than two transistors.

3. The low voltage detect and supply circuit of claim 1, wherein:
the at least one power supply transistor includes at least one p-channel insulated gate field effect transistor.

4. The low voltage detect and supply circuit of claim 1, wherein:
the at least one power supply transistor includes a plurality of p-channel insulated gate field effect transistors having source-drain paths arranged in parallel between the power supply node and the regulated supply node, and gates commonly coupled to the control node.

5. The low voltage detect and supply circuit of claim 1, wherein:
the detect circuit consists of a p-channel transistor having a source-drain path coupled between the power supply node and the control node and a gate coupled to the reference supply node.

6. The low voltage detect and supply circuit of claim 1, wherein:
the detect circuit comprises a p-channel detect transistor having a source-drain path coupled between the power supply node and the control node and a gate coupled to the reference supply node, the detect transistor having a channel length that is more than 150 times greater than the channel width.

7. The low voltage detect and supply circuit of claim 1, wherein:
the bias circuit consists of an n-channel transistor having a source-drain path coupled between the detect node and the reference supply node and a gate coupled to receive a bias voltage.

8. The low voltage detect and supply circuit of claim 7, wherein:
the bias circuit comprises an n-channel bias transistor having a source-drain path coupled between the detect node and the reference supply node that is biased to draw no more than about 15 nanoamps.

9. The low voltage detect and supply circuit of claim 1, further including:
a low voltage sustain circuit comprising,
at least one sustain transistor having a source connected to the power supply node, a gate coupled to a sustain bias node, a drain coupled to the regulated supply node,
a voltage drop detect circuit having a controllable impedance coupled between the sustain bias node and the reference supply node that provides an impedance that varies according to a potential between the reference supply node and the sustain bias node; and
a second bias circuit coupled between the power supply node and the sustain bias node that enables a bias current for the voltage drop detect circuit.

10. The low voltage detect and supply circuit of claim 9, wherein:
the voltage drop detect circuit and second bias circuit consist of no more than two transistors.

11. The low voltage detect and supply circuit of claim 1, wherein:
the source of the at least one power supply transistor is coupled to an array of memory cells.

12. The low voltage detect and supply circuit of claim 11, wherein:
the memory cells comprise static random access memory cells, each including a cross coupled transistor pair.

13. A circuit, comprising:
a low voltage detect circuit comprising
a first controllable impedance path coupled between a power supply node and a regulated voltage node that provides an impedance according to the potential at a control node, and
a threshold current path coupled between the power supply node and the control node that provides an impedance that switches from a low impedance to a high impedance when the potential between the power supply node and the control node falls below a predetermined potential; and
a memory cell array coupled to the regulated voltage node.

14. The circuit of claim 13, wherein:
the first controllable impedance path consists of an insulated gate field effect transistor.

15. The circuit of claim 13, wherein:
the threshold current path consists of a p-channel detect transistor, and the predetermined potential includes the threshold voltage of the p-channel insulated gate field effect transistor, and a voltage drop between the source and drain of the detect transistor.

16. The circuit of claim 13, further including:
a minimum voltage sustain circuit, comprising
a second controllable impedance path coupled between the power supply node and the regulated voltage node that provides an impedance according to the potential at a sustain bias node, and
a second threshold current path coupled between the reference supply node and the sustain bias node that provides an impedance that switches from a low impedance to a high impedance when the potential between the reference supply node and the sustain bias node falls below a predetermined potential.

17. A method of regulating an internal power supply node, comprising the steps of:
enabling a shorting current path between a power supply node and a regulated power supply node when a power supply voltage at the power supply node falls below a predetermined low voltage threshold; and
disabling the shorting current path between the power supply node and the regulated power supply node when the power supply voltage rises above the predetermined low voltage threshold; wherein
the low voltage threshold is established by a threshold voltage of a p-channel transistor and a bias voltage.

18. The method of claim 17, wherein:
the shorting current path comprises at least one p-channel supply transistor having a source-drain path coupled between the power supply node and the regulated power supply node; and
enabling the shorting current path between the power supply node and the regulated power supply node includes disabling a p-channel detect transistor when a potential between the power supply node and a gate of the detect transistor is less than the threshold voltage of the detect transistor.

19. The method of claim 17, further including:
enabling a sustaining current path between a power supply node and a regulated power supply node when a regulated power supply voltage at the regulated power supply node falls below a predetermined minimum supply voltage threshold; and
disabling the sustaining current path between the power supply node and the regulated power supply node when the regulated power supply voltage rises above the predetermined minimum supply voltage threshold; wherein
the minimum supply voltage threshold is established by a threshold voltage of at least two n-channel transistors having different threshold voltages.

20. The method of claim 19, wherein:
the sustaining current path comprises at least one n-channel supply transistor having a source-drain path coupled between the power supply node and the regulated power supply node; and
enabling the sustaining current path between the power supply node and the regulated power supply node includes enabling a p-channel sustain bias transistor when a potential at the regulated power supply node falls below the predetermined minimum supply voltage threshold.
